(19) United States
(12) Patent Application Publication
(10) Pub. No.: US 2009/0282917 A1
(43) Pub. Date: Nov. 19, 2009

(54) Integrated multi-axis micromachined inertial sensing unit and method of fabrication

(76) Inventor: Cenk Acar, Irvine, CA (US)

Correspondence Address: EDWARD S. WRIGHT, 1100 ALMA STREET, SUITE 207, MENLO PARK, CA, 94025, US

(21) Appl. No.: 12/122,875

(22) Filed: May 19, 2008

(51) Int. Cl. G01P 15/02; G01P 15/14; H01L 21/00

(52) U.S. Cl. 73/514.02; 73/504.02; 438/109; 257/E21.001

(57) ABSTRACT

Integrated micromachined inertial sensing unit with multi-axis angular rate and acceleration sensors and method of fabricating the same. Micromachined angular rate and acceleration sensors are integrated together with an application-specific integrated circuit (ASIC) in one compact package. The ASIC combines many separate functions required to operate multiple rate sensors and accelerometers into a single chip. The MEMS sensing elements and the ASIC are die-stacked, and electrically connected either directly using ball-grid-arrays or wirebonding. Through the use of a single package and single ASIC for multiple angular rate and acceleration sensors, significant reduction in cost is achieved.

### BACKGROUND OF THE INVENTION

1. Field of Invention

This invention relates generally to inertial sensors and, more particularly, to an integrated micromachined inertial sensing unit with multi-axis angular rate and acceleration sensors and to a method of fabricating the same.

2. Related Art

Electronic stability control systems for automobiles and other vehicles generally have one or more gyroscopes for yaw and/or roll rate measurements, and one or more accelerometers for longitudinal and/or lateral acceleration measurements. Such systems commonly have multiple gyroscopes and accelerometers on a circuit board, with each gyroscope and each accelerometer having its own separate application-specific integrated circuit (ASIC) for control and sensing functions, and each sensor and each ASIC being housed in its own package.

Common functional building blocks such as timing circuits, digital processors, and temperature sensors are duplicated in the ASICs for the different devices, and the separate packaging of each sensor and each ASIC requires additional assembly time and materials, which add significantly to the cost of the system. Separate packages also require more circuit board area, which further increases the cost of the system.

### SUMMARY OF THE INVENTION

In the inertial sensing unit and method of the invention, angular rate and acceleration sensors are formed on one or more MEMS dice, and the MEMS dice are stacked together with a single application specific integrated circuit (ASIC) die with operating circuitry for all of sensors on the MEMS dice. The sensors are interconnected with the circuitry on the ASIC die, and the stacked dice are packaged in a single package.

### BRIEF DESCRIPTION OF THE DRAWINGS

FIG. 1 is a vertical sectional view of one embodiment of an integrated, multi-axis, micromachined inertial sensing unit according to the invention.

FIG. 2 is a vertical sectional view of another embodiment of an integrated, multi-axis, micromachined inertial sensing unit according to the invention.

FIG. 3 is a vertical sectional view of another embodiment of an integrated, multi-axis, micromachined inertial sensing unit according to the invention.

FIG. 4 is a vertical sectional view of another embodiment of an integrated, multi-axis, micromachined inertial sensing unit according to the invention.

FIG. 5 is a vertical sectional view of another embodiment of an integrated, multi-axis, micromachined inertial sensing unit according to the invention.

FIG. 6 is a vertical sectional view of another embodiment of an integrated, multi-axis, micromachined inertial sensing unit according to the invention.

### DETAILED DESCRIPTION

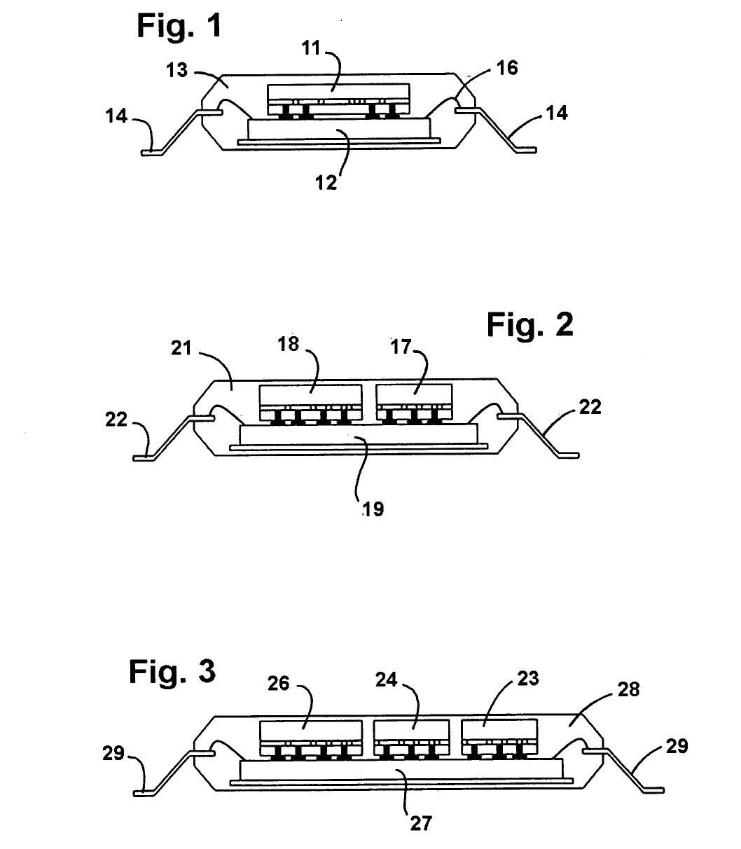

In the embodiment of FIG. 1, a chip or die 11 with both angular rate and acceleration sensors is stacked on top of an application specific integrated circuit (ASIC) chip or die 12 which contains operating circuitry for the sensors. The rate sensor and accelerometer are fabricated on a silicon substrate by microelectro-mechanical systems (MEMS) technology and can, for example, be of the type disclosed in co-pending application Ser. No. 11/734,156.

The rate sensor and the accelerometer can be either single-axis or dual-axis devices depending upon the application in which the sensing unit is to be used. Yaw, longitudinal acceleration, and lateral acceleration can, for example, be monitored with a single-axis rate sensor and a dual-axis accelerometer, and if roll is also to be monitored, the rate sensor can be a dual-axis device.

The MEMS die is encapsulated and hermetically sealed at the wafer level which, as discussed in greater detail below, simplifies the final packaging process and permits the use of less expensive packaging.

The ASIC chip includes circuitry for sensing, signal conditioning, and control of all of the sensing devices, with common functional building blocks for operating the rate sensors and accelerometers being combined and shared.

In the embodiment of FIG. 1, the MEMS die is flip-chip bonded to the ASIC die. Solder balls are formed on the upper side of the MEMS die by a suitable technique such as contact bumping during fabrication of the die. The die is positioned on top of the ASIC die in an inverted position, with the ball grid array formed by the solder balls aligned with contact pads on the ASIC die. The solder is then remelted to bond the two dice together and form electrical connections between the sensors on the MEMS die and the circuitry on the ASIC die.

With flip-chip bonding, the length of the electrical connections between the dice is kept to a minimum, which significantly reduces parasitic electrical effects. However, the interconnect patterns on the two dice have to be compatible, which can impose some constraints on the layouts of the devices and the circuitry on them.

The stacked dice are then encapsulated in an electrically insulative package 13, with electrically conductive leads or pins 14 extending therefrom for connection to external components such as conductors on a circuit board. Electrical connections between the ASIC die and the connecting pins are made by bonding wires 16.

With the MEMS sensing elements encapsulated and hermetically sealed at the wafer level, packaging requirements are significantly relaxed, and standard low-cost semi-conductor packaging techniques that do not have to provide hermetic sealing can be utilized. One common, low-cost technique that can, for example, be used is over-molded plastic packaging. These packages are fully compatible with the integrated structure, and if packaging stresses become an issue, gel coatings on the dice or plastic packages with pre-molded cavities can be used.

The embodiment of FIG. 2 is similar to the embodiment of FIG. 1, but with the two sensors being formed on separate MEMS dice instead of being included on a single die. Thus, a rate sensor is fabricated on a first MEMS die 17, and an accelerometer is formed on a second MEMS die 18. The two MEMS dice are positioned side-by-side and stacked on top of an ASIC die 19 which includes the circuitry for both the rate sensor and the accelerometer. As in the embodiment of FIG. 1, the rate sensor and the accelerometer can be either single-axis or dual-axis devices, and each of the MEMS dice is individually encapsulated and hermetically sealed.

The two MEMS dice are flip-chip bonded to the ASIC die, with the sensing devices on the MEMS dice thus being interconnected with the circuitry on the ASIC die.

The stacked dice are encapsulated in an electrically insulative package 21, with electrically conductive leads or pins 22 extending therefrom.

With the rate sensor and accelerometer on separate dice, each device can be fabricated separately in a process that is optimized for the particular type of device. Also, the rate sensor can be encapsulated in vacuum to provide higher quality factors, while the accelerometers can be encapsulated at higher pressures to achieve critical damping or over-damping.

In the embodiment of FIG. 3, two rate sensor dice 23, 24 and an accelerometer die 26 are stacked side-by-side on an ASIC die 27. Each rate sensor is a single-axis sensor, and the accelerometer is a dual-axis sensor, with each of the MEMS devices being individually encapsulated and hermetically sealed. The ASIC includes the circuitry for the two rate sensors and the accelerometer, and the MEMS dice are flip-chip bonded to the ASIC die. The stacked dice are encapsulated in an electrically insulative package 28, with electrically conductive leads or pins 29 extending therefrom.

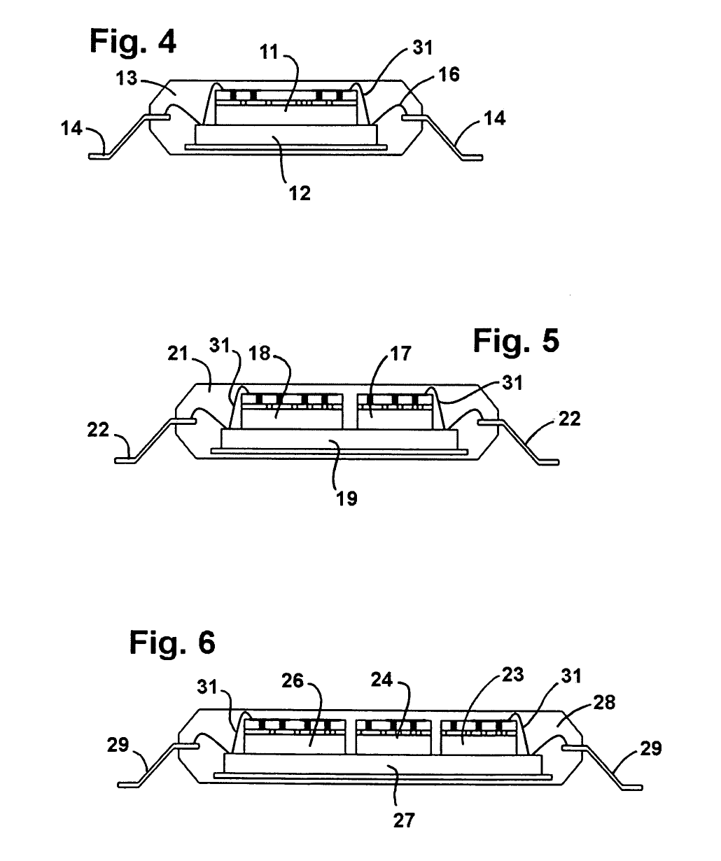

The embodiments of FIGS. 4-6 are similar to the embodiments of FIGS. 1-3, and like reference numerals designate corresponding elements in the corresponding embodiments. In the embodiments of FIGS. 4-6, however, the MEMS chips or dice are adhesively attached to the ASIC chips or dice with a die-stacking adhesive or epoxy, and the electrical connections between the sensing elements on the MEMS dice and the circuitry on the ASIC dice are made with bonding wires 31.

The wirebonding provides flexibility in the layout of both the MEMS devices and the ASIC. Unlike flip-chip bonding where the bonding pads of the MEMS and ASIC devices must be aligned exactly with each other, with wirebonding, the pad layouts are compatible if the pads along the sides of the dies are arranged in a matching sequence.

The invention has a number of important features and advantages. By combining multiple angular rate and acceleration sensors in a single package, sensors for monitoring yaw and/or roll, longitudinal acceleration, and lateral acceleration for electronic stability control in automotive applications can be integrated into a single component.

Packaging cost is significantly reduced by the use of a single package for multiple angular rate and acceleration sensors, and having the MEMS sensing elements individually encapsulated and hermetically sealed at the wafer level allows the use standard low-cost semiconductor packaging techniques, such as over-molded plastic packages that do not have to provide hermetic sealing.

The cost of the circuitry for the different sensors is significantly reduced by the use of a single ASIC that performs sensing, signal conditioning and control of all devices. Many common functional building blocks for operating the gyroscopes and accelerometers are combined and shared.

By integrating multiple angular rate and acceleration sensors into a single package, the total consumed circuit board area in the final application is reduced, thereby decreasing the overall system cost. In addition, the vertical stacking of the MEMS and ASIC dice minimizes the footprint of the package, thereby further reducing amount of circuit board area required and further decreasing the overall cost of the system.

Having a single ASIC and a single package minimizes the number of parts and results in a lesser number of failure modes and lower probability of failure of the complete unit.

While the invention has been disclosed with specific reference to electronic stability controls as used, for example in automotive brake systems, it can also be utilized in other applications such as inertial sensors for automotive airbag deployment systems, consumer electronics handheld devices, as well as aerospace and defense inertial MEMS sensors.

It is apparent from the foregoing that a new and improved inertial sensing unit and method have been provided. While only certain presently preferred embodiments have been described in detail, as will be apparent to those familiar with the art, certain changes and modifications can be made without departing from the scope of the invention as defined by the following claims.

1. An inertial sensing unit, comprising: micromachined angular rate and acceleration sensors formed on at least one MEMS die, a single application specific integrated circuit (ASIC) die with operating circuitry for all of the sensors, the MEMS and ASIC dice being stacked together with at least one of the dice on top of another, electrical connections between the angular rate and acceleration sensors and the circuitry on the ASIC die, and a single package enclosing the stacked dice.

2. The inertial sensing unit of claim 1 wherein each MEMS die is hermetically encapsulated.

3. The inertial sensing unit of claim 1 wherein each MEMS die is flip-chip bonded to the ASIC die.

4. The inertial sensing unit of claim 1 wherein each MEMS die is adhesively bonded to the ASIC die, and the sensors are connected to the circuitry in the ASIC by wire bonding.

5. The inertial sensing unit of claim 1 wherein an angular rate sensor and an accelerometer are formed on a single MEMS die.

6. The inertial sensing unit of claim 1 wherein an angular rate sensor is formed on one MEMS die, and an accelerometer is formed on a second MEMS die.

7. The inertial sensing unit of claim 1 wherein a first angular rate sensor is formed on one MEMS die, a second angular rate sensor is formed on a second MEMS die, and an accelerometer is formed on a third MEMS die.

8. The inertial sensing unit of claim 1 wherein the sensors provide single-axis rate sensing and dual-axis acceleration sensing.

9. An inertial sensing unit, comprising: a micromachined angular rate sensor and an acceleration sensor formed on a hermetically encapsulated MEMS die, a single application specific integrated circuit (ASIC) die with operating circuitry for both the angular rate sensor and the acceleration sensor, the MEMS die being stacked on top of the ASIC die with the sensors on the MEMS die being interconnected electrically with the circuitry on the ASIC die, and a single package enclosing the stacked dice.

10. The inertial sensing unit of claim 9 wherein the angular rate sensor is a dual-axis rate sensor.

11. The inertial sensing unit of claim 9 wherein the acceleration sensor is a dual-axis acceleration sensor.

12. An inertial sensing unit, comprising: a micromachined angular rate sensor on a first hermetically encapsulated MEMS die, an acceleration sensor on a second hermetically encapsulated MEMS die, a single application specific integrated circuit (ASIC) die with operating circuitry for both the angular rate sensor and the acceleration sensor, the MEMS dice being stacked on top of the ASIC die with the sensors on the MEMS dice being interconnected electrically with the circuitry on the ASIC die, and a single package enclosing the stacked dice.

13. The inertial sensing unit of claim 12 wherein the angular rate sensor is a dual-axis rate sensor.

14. The inertial sensing unit of claim 12 wherein the acceleration sensor is a dual-axis acceleration sensor.

15. The inertial sensing unit of claim 12 including a second rate sensor on a third MEMS die, with the third MEMS die also being stacked on the ASIC die and the second rate sensor being interconnected electrically with the circuitry on the ASIC die.

16. A method of fabricating an inertial sensing unit, comprising the steps of: forming angular rate and acceleration sensors on at least one MEMS die, stacking each MEMS die on top of a single application specific integrated circuit (ASIC) die with operating circuitry for all of sensors, interconnecting the sensors on each MEMS die with the circuitry on the ASIC die, and packaging the stacked dice in a single package.

17. The method of claim 16 including the step of hermetically encapsulating each MEMS die before the die is stacked on the ASIC die.

18. The method of claim 16 wherein an array of contact balls are formed on one side of each MEMS die, each MEMS die is placed on the ASIC die with the contact balls facing the ASIC die, and the contact balls are bonded to contact pads on the ASIC die.

19. The method of claim 16 wherein the sensors on each MEMS die are connected to contacts on the ASIC die by wirebonding.
